(19) United States
(12) Patent Application Publication
(10) Pub. No.: US 2006/0202250 A1
(43) Pub. Date: Sep. 14, 2006

(54) Storage capacitor, array of storage capacitors and memory cell array

(76) Inventors: Thomas Hecht, Dresden (DE); Uwe Schroeder, Dresden (DE); Till Schloesser, Dresden (DE); Stefan Jakschik, Dresden (DE); Alejandro Avellan, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/076,021

(22) Filed: Mar. 10, 2005

(51) Int. Cl. H01L 29/94

(52) U.S. Cl. 257/306

(57) ABSTRACT

A storage capacitor, suitable for use in a DRAM cell, is at least partially formed above a substrate surface and includes: a storage electrode at least partially formed above the substrate surface, a dielectric layer formed adjacent the storage electrode, and a counter electrode formed adjacent the dielectric layer, the counter electrode being isolated from the storage electrode by the dielectric layer, wherein the storage electrode is formed as a body which is delimited by at least one curved surface having a center of curvature outside the body in a plane parallel to the substrate surface. According to another configuration, the storage electrode is formed as a body which is delimited by at least one set having two contiguous planes, the two planes extending perpendicularly with respect to the substrate surface, a point of intersection of normals of the two planes lying outside the body.

### FIELD OF THE INVENTION

The invention relates to a storage capacitor, which can especially be used in a memory cell of a DRAM (Dynamic Random Access) memory. In addition, the present invention relates to an array of storage capacitors as well as to a memory cell array.

### BACKGROUND

Memory cells of a dynamic random access memory (DRAM) generally comprise a storage capacitor for storing an electrical charge which represents information to be stored, and an access transistor which is connected with the storage capacitor. The access transistor comprises a first and a second (source and drain) regions, a channel connecting the first and the second source/drain regions as well as a gate electrode controlling an electrical current flow between the first and second source/drain regions. The transistor usually is at least partially formed in the semiconductor substrate. The gate electrode forms part of a word line and is electrically isolated from the channel by a gate dielectric. By addressing the access transistor via the corresponding word line, the information stored in the storage capacitor is read out. In addition, by addressing the access transistor and transmitting an information signal via a bit line, an information is stored in the corresponding memory cell, which is assigned to the specific word line and bit line.

In currently used DRAM memory cells, the storage capacitor can be implemented as a trench capacitor. In a trench capacitor, for example, the storage electrode can be disposed in a trench which extends in the substrate in a direction perpendicular to the substrate surface. The storage electrode is isolated from the sidewalls of the trench by a dielectric layer acting as the capacitor dielectric, the sidewalls of the trench forming a counter electrode.

According to another implementation of the DRAM memory cell, the electrical charge is stored in a stacked capacitor, which is formed above the surface of the substrate.

FIG. 14 shows a cross-sectional view of an exemplary DRAM memory cell comprising a stacked capacitor. In FIG. 14, an access transistor comprising a first source/drain region 51 and a second source/drain region 52 is formed in a substrate 1. A gate electrode 53 is provided so as to control an electrical current flow between the first and the second source/drain regions 51, 52 respectively. The gate electrode 53 forms part of a word line 7. A bit line 8 is connected via a bit line contact 81 with the second source/drain region 52. As is shown in FIG. 14, the storage capacitor 2 is disposed above the semiconductor substrate surface 10. In particular, the storage capacitor 2 comprises a storage electrode 20 as well as a counter electrode 210. Both capacitor electrodes are formed of n⁺-doped polysilicon. A dielectrical layer 211 is disposed between the storage electrode and the counter electrode. A capacitor contact 24 electrically connects the first source/drain region 51 with the storage electrode 20. A BPSG (boron phosphorous silicate glass) layer 54 is disposed above the substrate surface 10 and electrically isolates the capacitor components from the substrate surface.

The characteristic feature of a DRAM cell is the retention time, i.e., the time during which information can be recognizably stored in the capacitor. In order to achieve good retention characteristics, a minimum capacitance of ˜25 fF/cell has to be maintained, even if the cell is shrunken in size. This can be achieved by keeping the surface area constant, despite the shrinking cell size (e.g. by using the third dimension), or by changing the capacitor materials (increasing the dielectric constant of the dielectric or using metal electrodes to reduce the charge space regions). For stacked capacitors, currently two different three-dimensional geometries are used: cup and cylinder. The cup geometry has the problem of the poor surface efficiency. The cylinder structure uses both sides of the inner electrode, but it is geometrically less stable. In particular, the problem of sticking cylinders is likely to occur. In addition, the benefit of the inner capacitor reduces if the groundrule is reduced to the order of the electrode thickness.

The article “Robust Memory Cell Capacitor using Multi-Stack Storage Node for High Performance in 90 nm Technology and Beyond”, by Lee et al., 2003 Symposium on VLSI Technologies, proposes a storage node structure comprising a cylinder shaped capacitor which is stacked on a box-shaped capacitor. For obtaining such a storage node, the electrode and the interelectrode dielectricum have to be deposited with a high aspect ratio.

### SUMMARY

In accordance with the present invention a storage capacitor is designed to have a large surface area even if a small ground rule is used, and the problem of sticking of the capacitor electrodes is avoided. Embodiments of the present invention provide a storage capacitor, an array of storage capacitors as well as a memory cell array.

In particular, the present invention provides a storage capacitor, suitable for use in a DRAM cell, the storage capacitor being at least partially formed above a substrate surface, the storage capacitor comprising: a storage electrode at least partially formed above the substrate surface, a dielectric layer formed adjacent the storage electrode, and a counter electrode formed adjacent the dielectric layer, the counter electrode being isolated from the storage electrode by the dielectric layer, wherein the storage electrode is formed as a body which is delimited by at least one curved surface, the at least one curved surface having a center of curvature outside the body, in a plane parallel to the substrate surface.

Alternatively, the storage electrode is formed as a body which is delimited by at least one set comprising two contiguous planes, the two planes extending perpendicularly with respect to the substrate surface, the point of intersection of the normals of the two plates laying outside the body.

### BRIEF DESCRIPTION OF THE DRAWINGS

The accompanying drawings are included to provide a further understanding of the present invention and are incorporated in and constitute a part of the specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A shows a perspective view of a storage electrode of the storage capacitor of the present invention;

FIGS. 1B and 1C cross-sections of two storage electrodes, respectively embodying the present invention;

FIGS. 2A and 2B illustrate plan views, respectively, of storage electrodes of the storage capacitor of the present invention;

FIGS. 3A and 3B show plan views of the storage electrodes of further embodiments of the storage capacitor of the present invention;

FIGS. 4A and 4B illustrate an array of storage electrodes of the array of storage capacitors of the present invention;

FIGS. 5 to 9 show steps of the method of manufacturing a storage electrode;

FIG. 10 shows an additional step of the method of manufacturing a storage electrode;

FIG. 11 shows an additional step of an alternative method of manufacturing a storage electrode;

FIG. 12 shows a cross-section of a memory cell incorporating the storage capacitor of the present invention;

FIGS. 13A and 13B show cross-sectional views, respectively, of a storage capacitor according to preferred embodiments of the present invention;

FIG. 13C shows a plan view of a preferred embodiment of the present invention; and

FIG. 14 shows a cross-section of a DRAM memory cell incorporating a conventional storage capacitor.

### DETAILED DESCRIPTION

In the following detailed description, reference is made to accompanying drawings, which form a part hereof and in which is illustrated by way of illustration, specific embodiments in which the invention may be practiced. In this regard, directional terminology, such as “top”, “bottom”, “front”, “back”, “leaving”, “trailing”, etc., is used with reference to the orientation of the figures being described. Because components of the embodiments of the present invention can be positioned in a number of different orientations, the directional terminology is used for purposes of illustration and is in no way limiting. It is to be understood, that other embodiments may be utilized, and structural or logical changes will be made without departing from the scope of the present invention. The following detailed description, therefore, is not to be taken in a limiting sense, and the scope of the present invention is defined by the appended claims.

In a first aspect, the present invention provides a storage capacitor comprising a storage electrode having an increased surface area, resulting in an increased capacity.

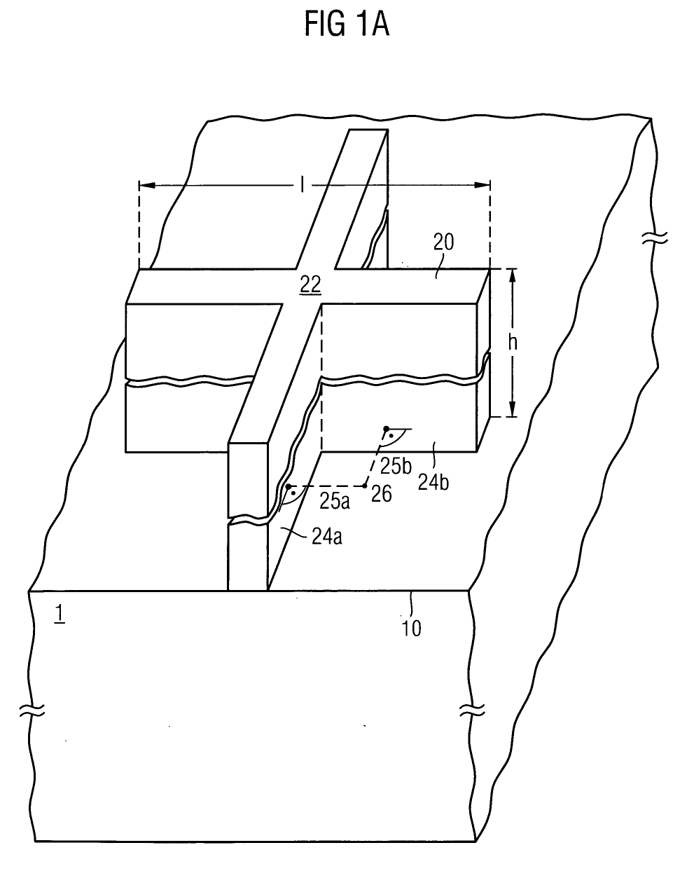

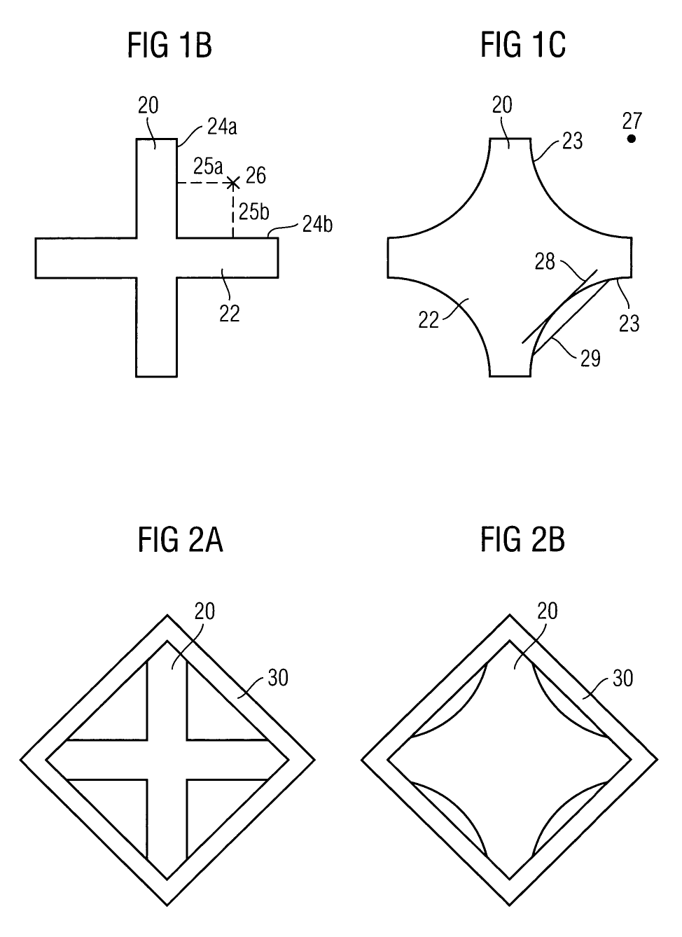

FIG. 1A shows a perspective view of a storage electrode 20 which forms part of the storage capacitor of the present invention. On the surface 10 of a substrate 1, the capacitor electrode 20 is formed of a conductive material which can be doped polysilicon or a metal having a high conductivity, in particular TiN, a metal silicide or Ru. The storage electrode is formed as a three-dimensional body 22 which is made up of four rectangular parallelepipeds. In particular, the cross-shaped body shown in FIG. 1A has a height h of 1 to 3 μm, and a length 1 of 10 to 30 nm, for example. As can be seen from FIG. 1A, the body constituting the storage electrode is delimited by four sets, each of the four sets comprising two contiguous planes 24a, 24b, the two planes 24a, 24b extending perpendicularly with respect to the substrate surface 10, a point of intersection 26 of the normals 25a, 25b of the two planes 24a, 24b lying outside the body.

As can also be seen from FIG. 1B, the two normals 25a and 25b extend perpendicular with respect to the two planes 24a and 24b, respectively. The point of intersection 26 of the two normals 25a and 25b lies outside the storage electrode 20. Stated differently, the surface area of the storage electrode is enlarged by cutting pieces from a cube or a rectangular parallelepiped or a column.

FIGS. 1B and 1C show plan views of exemplary storage electrodes of the storage capacitor according to the present invention.

As is shown in FIG. 1B, for example the cross-section of the storage electrode can have the shape of a cross, as is shown in FIG. 1A in a perspective view.

In addition, as is shown in FIG. 1C, in a cross-section parallel to the substrate surface, the capacitor electrode 20 can have the shape of a cross, in which the corners are not connected by straight, angled lines but by segments of a circle, especially quarter circles. Stated differently, in FIG. 1C, the storage electrode 20 is formed as a body 22 which is delimited by four curved surfaces 23, each of the four curved surfaces 23 having a center of curvature 27. In particular, the center of curvature denotes a point around which the surface is curved. In other words, the center of curvature is surrounded by the curved surface. Stated differently, in the cross-sectional view shown in FIG. 1C, the tangent lines 28 of the curved surface 23 lie within the body 22 of the storage electrode, whereas the secant 29 of the curved surface 23 lies outside the body of the storage electrode. Essentially, a plurality of concave cutouts are formed in a cube-like structure.

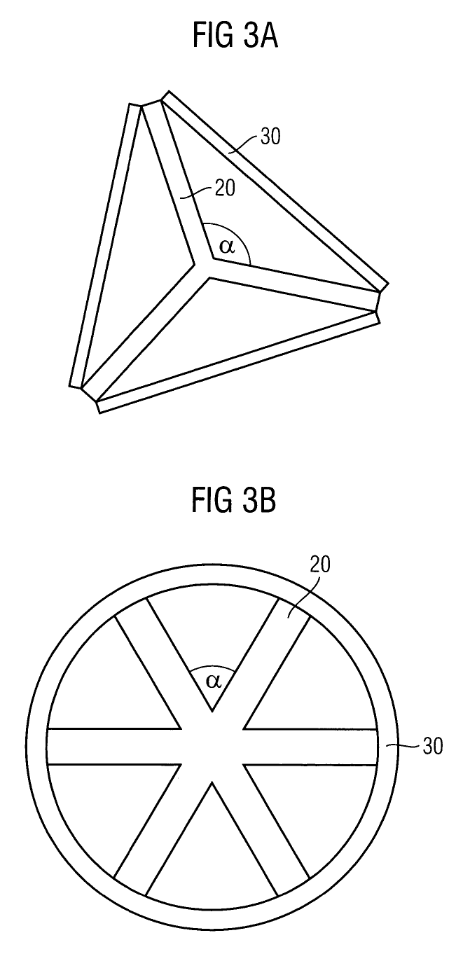

FIGS. 2A and 2B show plan views of further exemplary storage electrodes of the present invention. In particular, according to a preferred embodiment of the present invention, the storage capacitor further includes stabilizing elements or support structures 30 which are made of an isolating material and additionally provide a mechanical stability of the storage electrode.

In particular, any of the storage capacitors as defined in the appended claims preferably comprises a support structure being in contact with at least two circumferential points of the body of the storage electrode. The support structure which is made of an isolating material can have the same height or a smaller height than the body of the storage electrode. To be more specific, the support structure can be arranged in the upper portion of the storage electrode.

For example, if the storage electrode has the shape of a cross in a cross-sectional view parallel to the substrate surface, the support structures 30 can be arranged so as to connect the corners of the cross, as can be seen from FIG. 2C.

As is shown in FIG. 2D, if the storage electrode 20 has the form of a cross having segments of a circle connecting the corners of the cross, the support structures 30 can be arranged so as to connect the corners of the cross. Accordingly, the corners of the cross are connected by straight lines.

FIG. 3 shows further embodiments of the present invention, in which the storage electrode is formed of at least three crossing or contiguous beams in a cross-section parallel to the substrate surface. In particular, an angle between two of the at least three beams is 45 to 135°.

As is shown in FIG. 3A, the storage electrode can be made up of three beams, wherein an angle a between two neighboring beams is 120°. Optionally, support structures 30 can be provided, so as to connect the corners of the storage electrode, the support structures being made of an isolating material. The support structures 30 can be formed as straight lines or segments of a circle or have an arbitrary shape. The support structures can have the same or a smaller height than the body of the storage electrode.

In addition, as is shown in FIG. 3B, the storage electrode can be made up of three crossing beams, wherein an angle α between neighboring beams is 45°. Thereby, a storage electrode having a greatly increased surface area, and, consequently, having a greatly increased storage capacity can be provided. Optionally, support structures 30 made of an isolating material can be provided. In particular, the support structures 30 can be formed as straight lines or as segments of a circle or have an arbitrary shape. For example, there can be one support structure having the shape of a ring.

As can be seen from FIG. 1A, for example, in the shown geometry the surface area being very close to the next neighbor is reduced with respect to conventional storage electrodes. Since the adhesion force gets larger with smaller distance and increasing area, a reduction of this area is important in order to reduce or avoid sticking of adjacent capacitors.

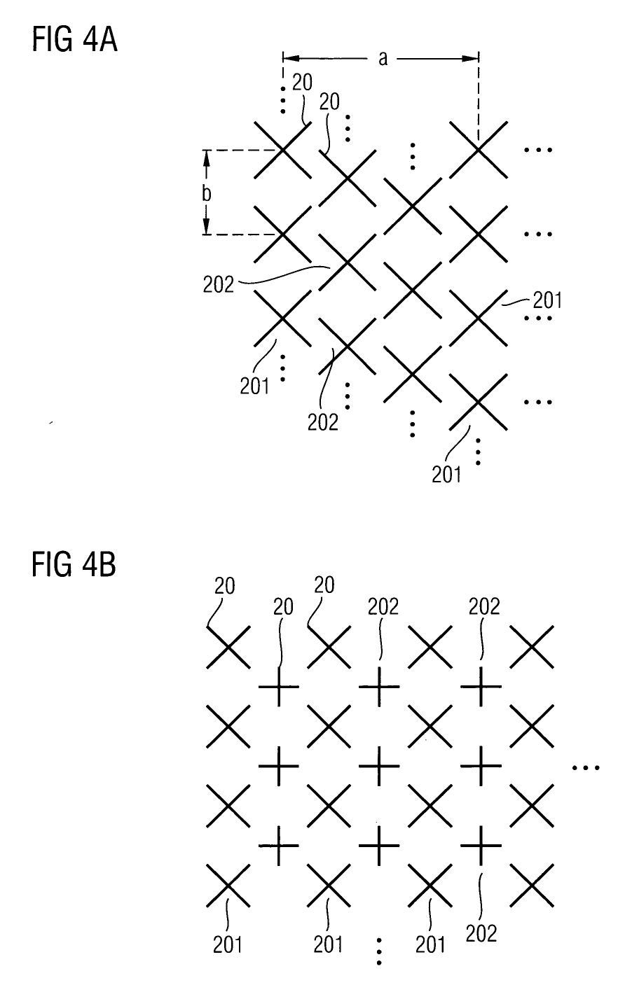

FIG. 4 shows exemplary arrays of storage electrodes of the corresponding array of storage capacitors according to the present invention, respectively. As is clearly to be understood, the array of storage electrodes can be implemented with any of the storage electrodes which are defined in the appended claims.

As is generally known, a memory device comprises a memory cell array, comprising an array of storage capacitors. FIGS. 4A and 4B show embodiments of arrays of storage electrodes, each of the storage electrodes forming part of a storage capacitor, respectively.

According to an embodiment of the present invention, the array of storage capacitors comprises a first set and a second set of storage capacitors 201 and 202, the storage capacitors of the first and second sets being arranged in a lattice, respectively, wherein a distance of adjacent storage capacitors within a set in a first direction is value “a” and a distance of adjacent storage capacitors in a second direction is value “b”, the first direction being perpendicular to the second direction. According to this embodiment, the lattice of the first set of storage capacitors is translated (offset) with respect to the lattice of the second set of storage capacitors by a distance in the first direction smaller than value “a” and a distance in a second direction smaller than value “b”, whereby the sets of storage capacitors are essentially arranged in interleaved rows and columns of storage capacitors. As is shown in FIG. 4A, the storage electrodes are shifted against each other, so that a dense array of storage electrodes can be obtained.

In other words, the first set of storage capacitors forms a two dimensional array arranged in regular rows and columns, and the second set of storage capacitors forms another two dimensional array, wherein the two arrays are overlaid in an interlaced manner, with alternating rows and columns of the first and second set, wherein the storage capacitors of the first set are offset in two dimensions (i.e., in the row direction and in the column direction in a plane parallel to the substrate surface) with respect to the storage capacitors of the second set. As shown in FIG. 4A, more than two sets of storage capacitors can be interlaced in this manner.

According to a second embodiment of the invention, the array of storage capacitor comprises a first and a second set of storage capacitors 201 and 202, the storage capacitors of the first set being rotated around an axis perpendicular to the substrate surface with respect to the storage capacitors of the second set, each of the storage capacitors of the first set being disposed adjacent at least one storage capacitor of the second set.

FIG. 4B shows a corresponding arrangement of the storage electrodes. In particular, the pattern shown in FIG. 4B is made up of a first and a second lattice of storage electrodes, wherein the second lattice is rotated and translated with respect to the first lattice of storage electrodes. Thereby the storage electrodes are further stabilized, and a more dense pattern of storage electrodes is obtained.

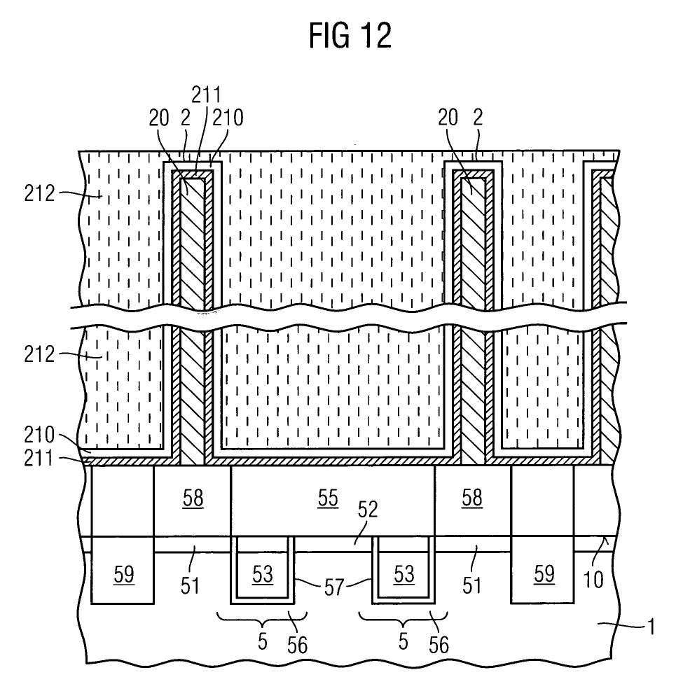

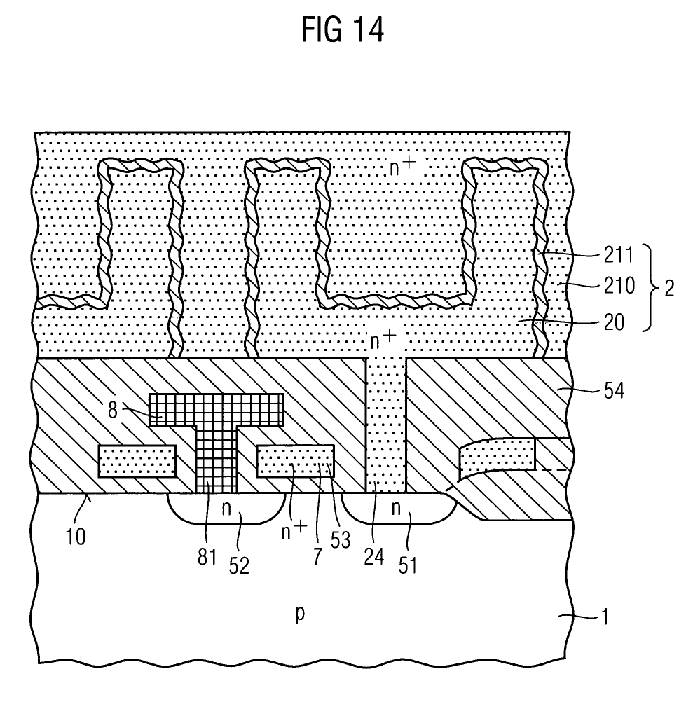

In the following, a method of manufacturing a storage electrode of the present invention will be described with reference to FIGS. 5 to 11. FIG. 5 shows a cross-sectional view of a semiconductor substrate 1 having a surface 10. The substrate 1 can be any arbitrary substrate on which a capacitor can be built. In particular, the substrate 1 can be a semiconductor substrate, e.g., a silicon substrate, having, for example, layers, in particular, conducting and isolating layers deposited thereon. In particular, the semiconductor substrate can be processed in such a manner that an access transistor, as is shown in FIG. 12 or 14, for example, is built therein.

In a first step, contact areas 58, which are, for example, made of a conducting material such as tungsten or others, are formed on the surface 10 of the substrate 1. To this end, first, a Si₃N₄ layer 55 is deposited on the surface 10. Subsequently, the contact areas 58 are photolithographically patterned so as to define openings in the Si₃N₄ layer. Thereafter, a conducting material such as tungsten is deposited and, thereafter, a CMP or back-etching step is performed so that tungsten is left only in the openings in the silicon nitride layer. As a consequence, as is shown in FIG. 5, contact areas 58 which are isolated from each other by Si₃N₄ regions 55 are formed on the surface 10. Thereafter, a SiO₂ layer is formed on the resulting surface by a generally known method. For example, the SiO₂ layer 31 can be formed by a CVD (chemical vapor deposition) step using TEOS (tetraethylorthosilicate) as a starting material. The thickness of the SiO₂ layer 31 is approximately equal to the height of the completed storage electrode which is to be formed. For example, the thickness of the SiO₂ layer 31 can be 2 μm or more.

In the next step, first openings 32 are photolithographically defined in the SiO₂ layer 31. In particular, by patterning the openings 32, a cross pattern having stripes intersecting at an angle of 90° is formed. For example, this cross pattern can be implemented by using a mask having a pattern of lines and spaces for a first lithographic step, and by using the same mask which is rotated by 90° to form the openings 32 which are perpendicular to the openings which have been formed in the previous step.

After photolithographically defining the openings 32, the openings 32 are etched by a dry etching step. In this step, the openings 32 can be etched so that they extend to the surface of the Si₃N₄ regions 55. Alternatively, they can as well be etched to any predetermined depth, for example, by 50 to 200 nm. If a support structure is to be formed in the openings 32 in a later step, a depth of, for example, 50 to 200 nm will be sufficient so as to obtain the desired supporting action.

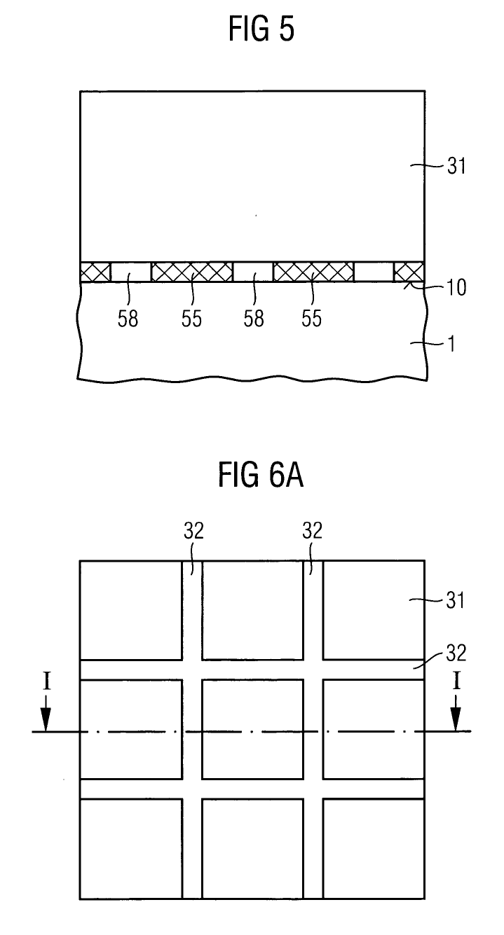

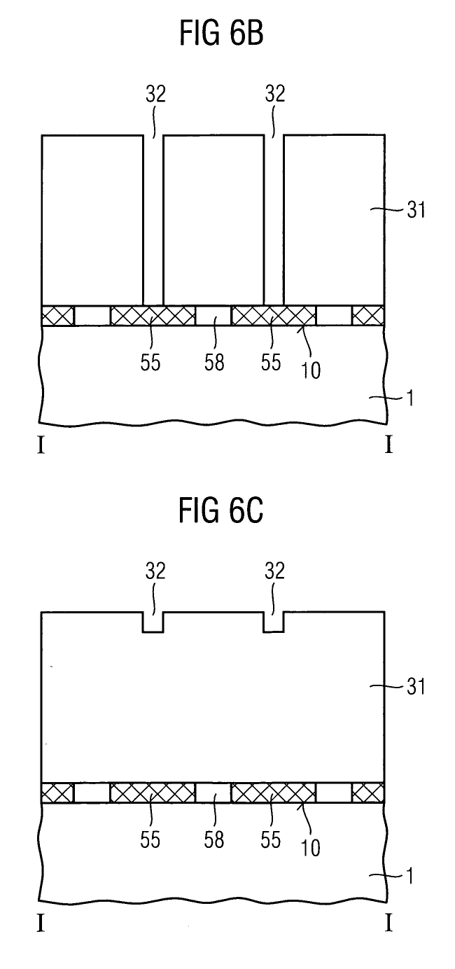

FIG. 6A shows a plan view on the resulting structure. Squares of SiO₂ material are isolated from each other by the openings 32, the openings 32 forming a cross pattern.

FIG. 6B shows a cross-sectional view along I and I in FIG. 6A. As can be seen, the openings 32 extend to the Si₃N₄ regions 55 formed on the substrate surface 10. In particular, the width of the openings 32 can be approximately 20 to 30 nm. Optionally, the openings 32 having a high aspect ratio can as well be formed by a spacer process. In addition, the distance between parallel openings 32 can be 70 to 200 nm or, differently stated, 2*F to 4*F wherein F denotes the minimum structural features size which can be obtained by the technology employed. For example, F can be 30 to 100 nm.

FIG. 6C shows a cross-sectional view along I and I in FIG. 6A in an embodiment in which the openings 32 are not etched to the surface of the Si₃N₄ regions 55 but to a smaller depth.

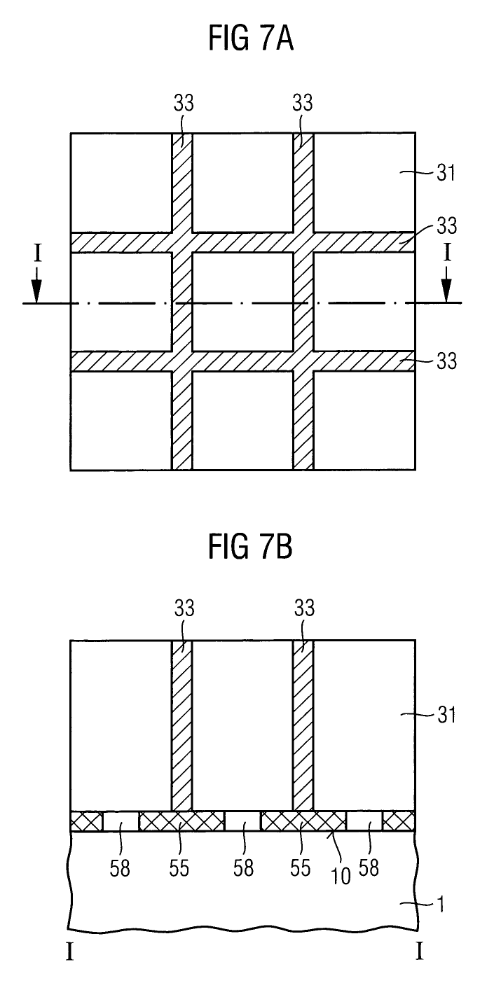

In a next step, an isolating fill material 33, which can be etched selectively with respect to SiO₂, is filled in the openings 32. For example the openings 32 can be filled with Al₂O₃. To this end, first, the fill material is deposited as a layer. Thereafter, a CMP step or a planarizing etching step is performed so as to remove excessive fill material portions. As a result, the structure shown in FIG. 7 is obtained. FIG. 7A shows a plan view on the resulting structure, wherein the openings 32 are filled with the fill material 33. FIG. 7B shows a cross-sectional view between I and I, showing that the openings 32 are filled with the isolating material 33.

In the next step, a second cross pattern, which is rotated by 45° with respect to the formerly formed cross pattern made of the fill material 33, is defined in the SiO₂ layer 31. For example, the second cross pattern can be obtained by photolithographically patterning a photoresist layer with the same mask which has been used for the lithographic step described with reference to FIG. 6. To this end, again, two separate lithographic steps are performed so as to correspondingly expose the photoresist layer. After developing the photoresist layer, second openings 34 are etched in the SiO₂ layer 31, for example by a dry oxide etch which is selective with respect to the fill material 33. For example, the second openings 34 can be etched by plasma etching.

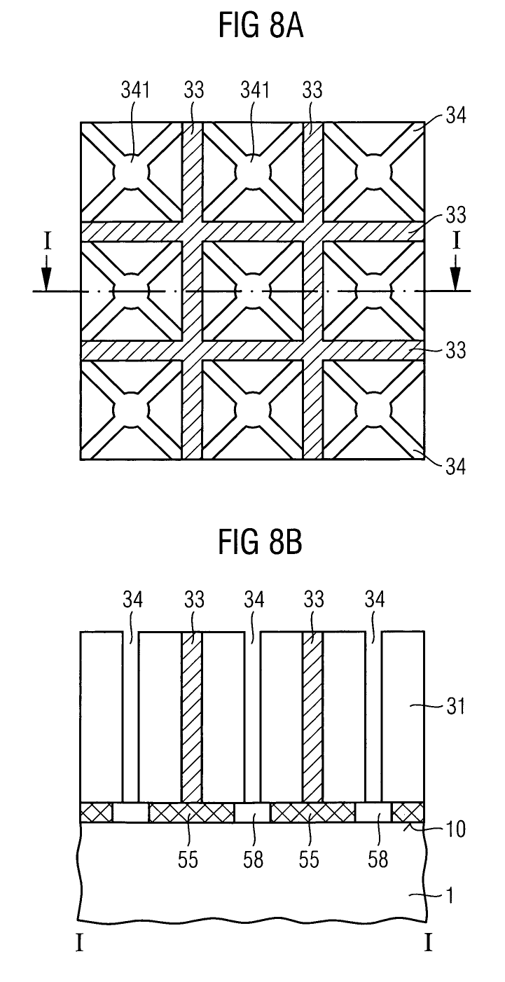

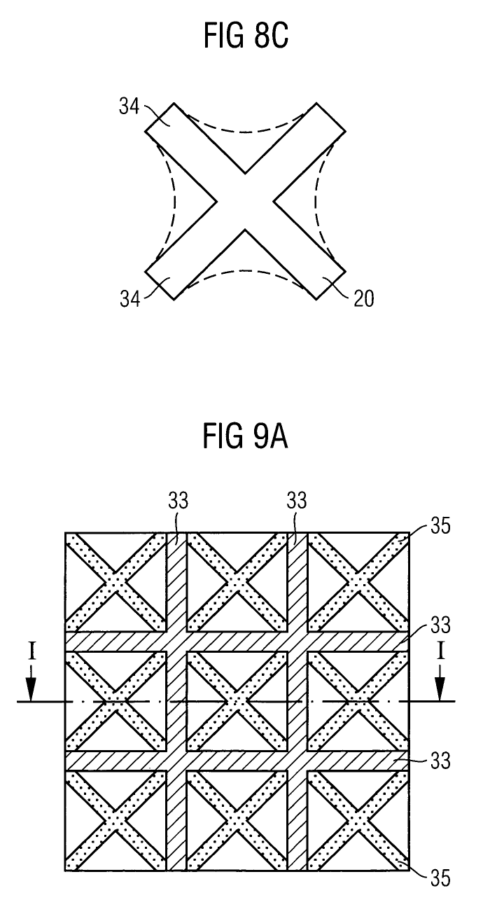

FIG. 8A shows a plan view on the resulting structure. As can be seen from FIGS. 8A and 8B, the crossing points 341 of the second openings 34 are disposed directly above the contact areas 58. By slightly over-etching the openings 34 in this process step, crosses can be obtained, in which, in a plan view, the corners are connected with curved lines or segments of a circle. This is illustrated in more detail in FIG. 8C.

FIG. 8B shows a cross-sectional view of the resulting structure between I and I. As can be seen, the second openings 34 are directly above the contact areas 58, whereas the first openings 32 which are filled with a fill material 33 are formed above the Si₃N₄ regions 55.

FIG. 8C shows a plan view on a cross which is formed in the process step shown in FIG. 8A. In particular, by performing an anisotropic etching step which exactly etches the lines which have been defined in the lithographic step, the structure shown by full lines is obtained. However, if a slight over-etching step is performed, a structure indicated by broken lines is obtained. Accordingly, a cross having corners which are connected by curved lines or segments of a circle can be obtained.

Differently stated, according to the present invention, the storage electrode of the storage capacitor is obtainable by photolithographically patterning a cross pattern with two sets of parallel lines, the first set intersecting the second set at an angle of 90°, and, thereafter, performing an etching step, which can be performed as an overetching step.

In the next step, an electrode material, such as TiN, a metal silizide or ruthenium, in particular a metal having a high conductivity, is filled in the openings 34. To this end, preferably, a layer of the material 35 is deposited, and thereafter, a CMP or planarizing dry etching step is performed so as to remove excessive material.

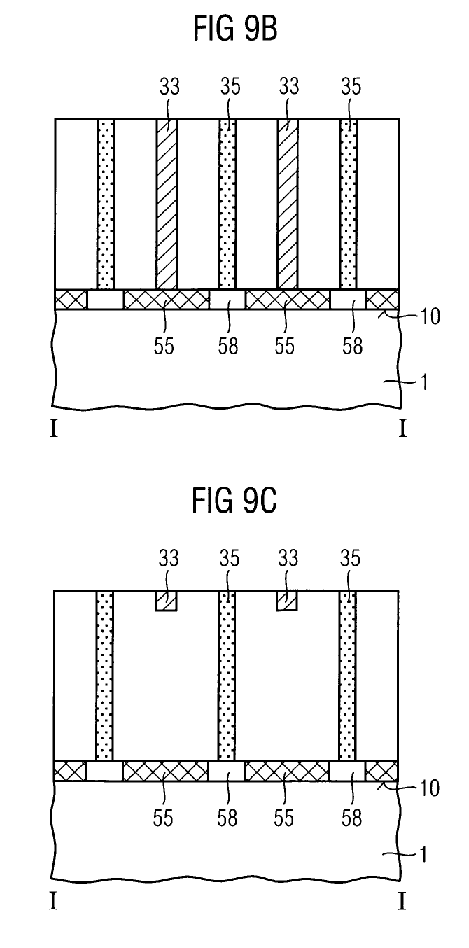

The resulting structure is shown in FIG. 9. In particular FIG. 9A shows a plan view on the resulting structure, whereas FIG. 9B shows a cross-sectional view between I and I in FIG. 9A. As can be seen from FIG. 9B, the openings 34 are filled with the conductive material 35, which is now in contact with the contact areas 58.

In addition, FIG. 9C shows a cross-sectional view between I and I in FIG. 9A in an embodiment, in which in the step of etching the openings 32 which has been described with reference to FIG. 6C, the 32 openings have been etched to a predetermined depth. In FIG. 9C, the openings filled with the fill material 33 do not extend to the Si₃N₄ regions 55.

In the next step, according to a first embodiment, the SiO₂ layer 31 and the fill material 33 are removed by wet etching. In particular, by simultaneously removing the fill material 33, this etching step can be a very fast etching step since in this case the SiO₂ material is laterally etched as well. For fully exploiting this fast lateral etching step, it is advantageous to have the openings 32 completely etched as is shown in FIG. 6B, for example.

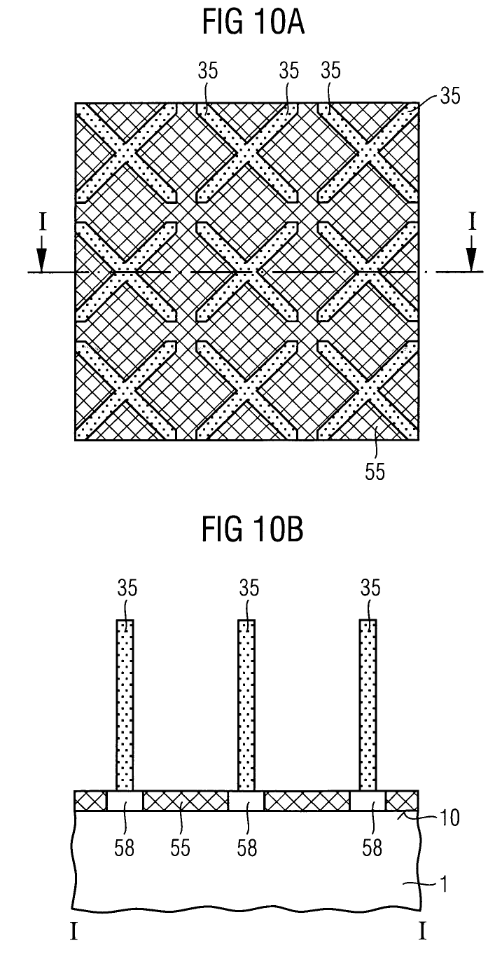

The resulting electrode structure is shown in FIG. 10. In particular FIG. 10A shows a plan view of the resulting structure. As can be seen, crosses made of the electrode material 35 are formed on a Si₃N₄ surface. The crosses are free-standing, so that the full surface thereof can be used as capacitor area. FIG. 10B shows a cross-sectional view between I and I. As can be seen, the crosses made of the electrode material 35 are protruding from the surface of the Si₃N₄ layer 55.

The storage capacitor can be completed in a known manner by forming a dielectric and a top electrode on top of the storage electrode as will be explained later.

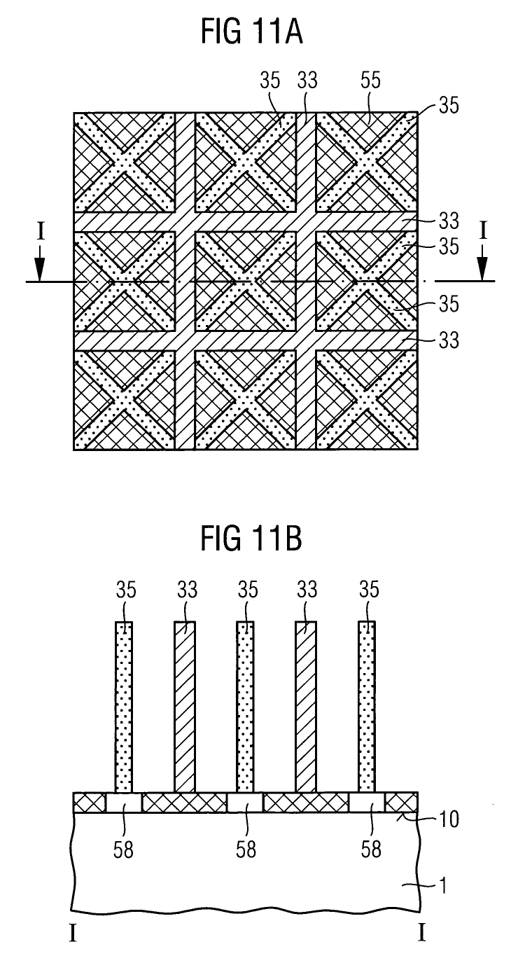

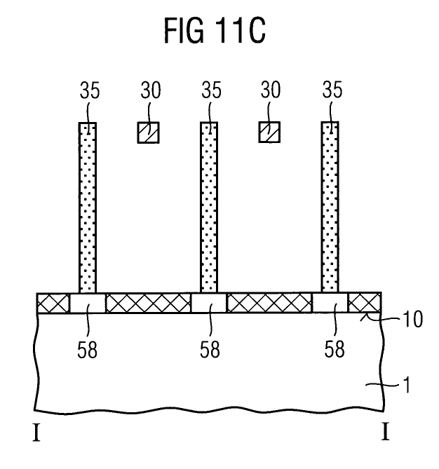

As an alternative to the process step described with reference to FIG. 10, the step of etching the SiO₂ layer 31 can be performed so that the fill material 33 is not removed. As a consequence, the structure shown in FIG. 11 is obtained. In particular, FIG. 11A shows a plan view on the resulting structure, in which the corners of the crosses are connected by a support structure 30 made of the fill material, respectively. Thereby, a mechanical stabilization is achieved. FIG. 11B shows a cross-sectional view of the resulting structure between I and I.

According to an embodiment of the present invention, the support structure 30 can have a smaller height than the storage electrode and can in particular be arranged in the upper portion of the storage electrode, as is shown in FIG. 11C. In particular, the support structure 30 can have a height of approximately 50 to 200 nm. In particular, the support structure 30 having a smaller height than the storage electrode can be obtained by etching the upper portion of the isolating layer 31 as has been described with reference to FIG. 6C.

For completing the storage capacitor, first, a conformal dielectric layer is deposited by generally known methods. Examples of the dielectric layer material include generally known dielectric materials such as SiO₂, Si₃N₄ or a combination thereof, or a so-called high-k material, such as Al₂O₃ or AlHfO. Finally, the material of the counter electrode is deposited on the resulting structure. Examples of the material of the counter electrode comprise TiN, Ru, metal silicides and polysilicon.

FIG. 12 shows a cross-sectional view of an exemplary DRAM memory cell incorporating the capacitor 2 of the present invention. Due to a different memory cell array layout, the cross-sectional view of FIG. 12 is not directly obtained from the process steps described with reference to FIGS. 5 to 11. Nevertheless, FIG. 12 shows an embodiment of the present invention.

As is shown in FIG. 12, the access transistor 5 of the DRAM memory cell comprises a first and a second source/drain regions 51, 52, a gate electrode 53 for controlling the conductivity of a channel 55 which is formed between the first and the second source/drain regions 51, 52. The gate electrode 53 forms part of a word line and is electrically isolated from the silicon substrate material 1, such as a p-doped silicon substrate, by a gate dielectric 57, as is commonly used. The first and the second source/drain regions 51, 52 are for example implemented as n-doped portions.

The storage electrode 20, which is formed in the manner as described above, is connected with the first source/drain region 51 of the access transistor. A counter electrode 210 is disposed above the storage electrode 20 and electrically isolated from the storage electrode 20 by the dielectric layer 211. An isolating cover layer 212 which can be made of SiO₂ or BPSG (bor phosphorsilicate glass) is finally deposited.

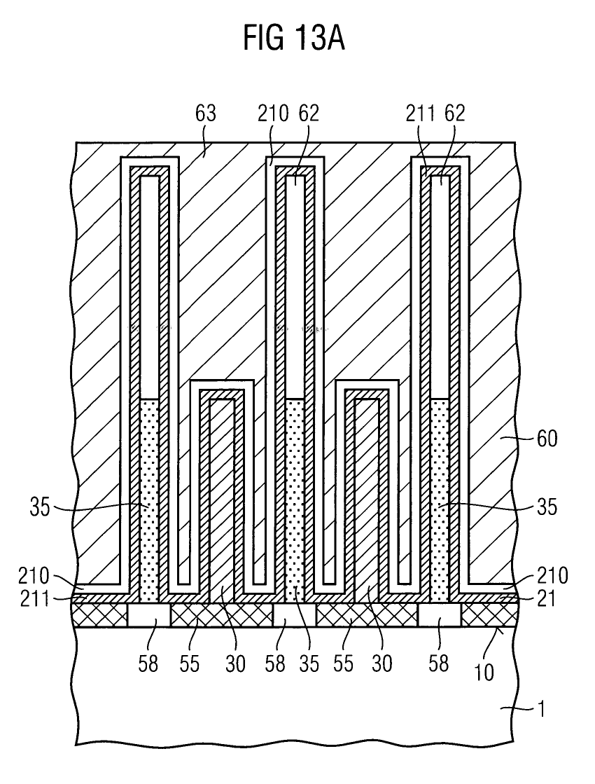

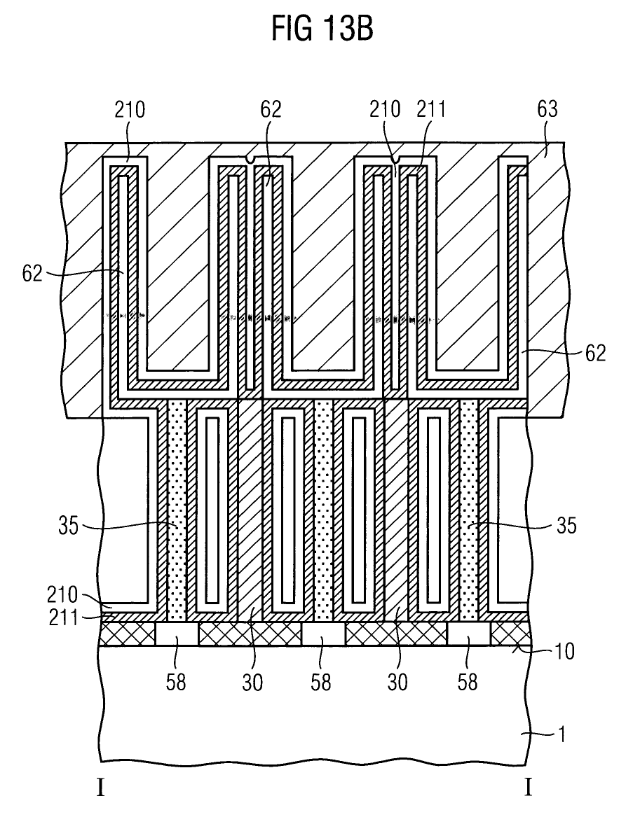

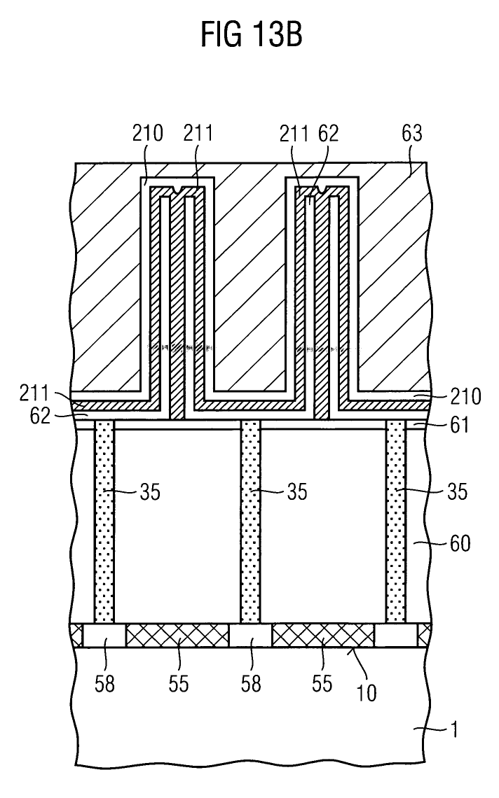

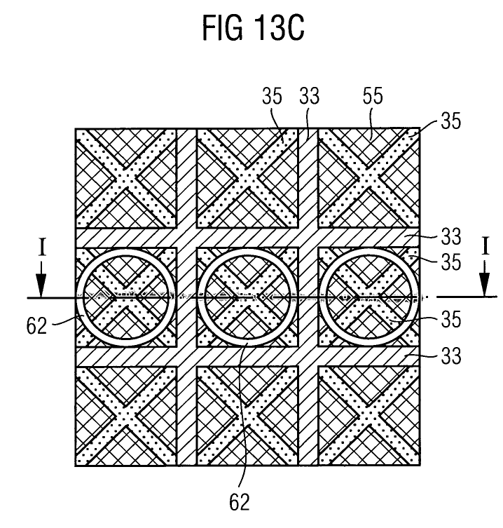

In the shown layout, two access transistors are arranged side by side so that they share a common bit line contact (not shown in the cross-sectional view), which is connected with the second source/drain region 52. Pairs of adjacent access transistors are electrically isolated from each other by isolation structures 59. The first source/drain region 51 is connected with a capacitor contact 58. The capacitor 2 has the structure as described above. In addition, the capacitor can have the structure as shown in FIG. 13A or 13B.

As has been shown in the foregoing, by the present invention, a storage capacitor having an enlarged capacitance is obtained. In addition, as can be for example gathered from FIG. 10A, the surface area of each of the capacitors being very close to its next neighbor, is reduced. As a consequence, since the adhesion force gets larger with smaller distance and increasing area, sticking of adjacent capacitors can be avoided. As a consequence, the mechanical stability of the resulting storage capacitors is improved. By forming a support structure 30 integrally with the storage electrode, the mechanical stability of the storage capacitor can be further improved.

FIGS. 13A and 13B show preferred embodiment of the present invention, in which the storage capacitor comprises a first storage electrode having a structure as described above, and additionally, a second storage electrode, which can be formed in a conventional manner as a cylinder or a cup. Alternatively, the second storage electrode can as well have the structure as described above.

In particular, the storage capacitor of FIGS. 13A and 13B comprises a first storage electrode being at least partially formed above the substrate surface, the first storage electrode being formed as a body which is delimited by at least one curved surface, the at least curved surface having a center of curvature outside the body in a plane parallel to the substrate surface.

Alternatively, the first storage electrode can be formed as a body which is delimited by at least one set comprising two contiguous planes, the two planes extending perpendicularly with respect to the substrate surface, a point of intersection of normals of the two planes lying outside the body.

According to the present embodiment, the storage capacitor further comprises a second storage electrode being formed above the first storage electrode and being electrically connected with the first storage electrode, a dielectric layer being formed adjacent the first and second storage electrodes, and a counter electrode, formed adjacent the dielectric layer, the counter electrode being isolated from the first and second storage electrodes by the dielectric layer.

Preferably, the storage capacitor further comprises a support structure made of an isolating material, the support structure being in contact with at least two circumferential points of the body of the first storage electrode.

Preferably, the second storage electrode is formed as a body which is delimited by at least one set comprising two contiguous planes, the two planes extending perpendicularly with respect to the substrate surface, a point of intersection of normals of the two planes lying outside the body.

Alternatively, the second storage electrode is formed as a body which is delimited by at least one curved surface, the at least curved surface having a center of curvature outside the body in a plane parallel to the substrate surface.

As a further alternative, the second storage electrode can be formed in the same manner as a conventional storage electrode, and, in particular, can have the shape of a cylinder or a cup.

The first and the second storage electrodes are connected with each other. The material of the second storage electrode can be TiN, Ru, a metal silicide or polysilicon. On top of the second storage electrode, a capacitor dielectric, as is generally known, is deposited so as to be in contact with the first and second storage electrodes. Thereafter, a counter electrode is formed in a generally known manner.

For forming the second storage electrode, for example, starting from the structure shown in FIG. 10B, an SiO₂ layer is deposited by generally known methods. The SiO₂ layer has a thickness which is equal to the height of the storage electrode to be completed. Subsequently, the same process steps as have been described with reference to FIG. 5 to 10A are performed so as to form the second storage electrode which is electrically connected with the first storage electrode. In particular, the structure of FIG. 10B having the SiO₂ layer deposited thereon corresponds to the structure shown in FIG. 5, with the top portions of the storage electrodes 35 corresponding to the contact areas 58 of FIG. 5. Thereafter, the second storage electrode 62 is placed so as to be in contact with the electrode material 35 of the first storage electrode. In the next step, the SiO₂ layer is removed. Finally, a dielectric layer 211 and a counter electrode 210 are deposited by generally known methods, followed by a layer 63 of an isolating material such as SiO₂. The resulting structure is shown in FIG. 13A.

According to another embodiment, the second storage electrode is formed above the structure shown in FIG. 11A. In particular, a conventional storage electrode having the shape of a cup is formed above the array of first storage electrodes. For implementing this embodiment, starting from the structure shown in FIG. 11A, the SiO₂ layer 60 having the thickness of the final height of the storage capacitor is deposited. Then, the second storage electrode is formed by generally known methods. In particular, the SiO₂ layer 60 is patterned and the material of the second storage electrode 62 is deposited. After forming the dielectric layer 211 and the counter electrode 210, followed by the deposition of an isolating layer 63, the structure shown in FIG. 13B is obtained. In particular, the complicated cross-sectional view of FIG. 13B results from the specific axis along which the cross-sectional view is taken. FIG. 13C shows an exemplary plan view of this embodiment. In particular, in FIG. 13C the position of each of the second storage electrodes is shown.

In addition, the second storage electrode can be implemented in an arbitrary manner, for example, having a shape of a box or a cube made of a conducting material.

By this embodiment, the storage capacitor 2 having a greatly enlarged surface area and, consequently, an increased capacitance can be obtained.

What is claimed is:

1. A storage capacitor, suitable for use in a DRAM cell, the storage capacitor being at least partially formed above a substrate surface, the storage capacitor comprising:
a storage electrode being at least partially formed above the substrate surface;
a dielectric layer being formed adjacent the storage electrode; and
a counter electrode, formed adjacent the dielectric layer, the counter electrode being isolated from the storage electrode by the dielectric layer;
wherein the storage electrode is formed as a body which is delimited by at least one curved surface, the at least one curved surface having a center of curvature outside the body in a plane parallel to the substrate surface.

2. A storage capacitor according to claim 1, wherein the body is delimited by four segments of a circle in a cross-section parallel to the substrate surface.

3. A storage capacitor according to claim 1, wherein the body is delimited by four segments of a circle and four straight lines in a cross-section parallel to the substrate surface.

4. A storage capacitor according to claim 1, wherein, in a cross-section parallel to the substrate surface, the body comprises at least three crossing beams.

5. A storage capacitor according to claim 4, wherein an angle between two of the at least three beams is 45° to 135°.

6. A storage capacitor according to claim 1, wherein in a cross-section parallel to the substrate surface the body comprises at least three contiguous beams.

7. A storage capacitor according to claim 1, further comprising a support structure made of an isolating material, the support structure being in contact with at least two circumferential points of the body of the storage electrode.

8. A storage capacitor according to claim 7, wherein the support structure has the same height as the body of the storage electrode.

9. A storage capacitor according to claim 7, wherein the support structure has a smaller height than the body of the storage electrode.

10. A storage capacitor according to claim 1, wherein the storage electrode is made of TiN, Ru or a metal silicide.

11. A storage capacitor, suitable for use in a DRAM cell, the storage capacitor being at least partially formed above a substrate surface, the storage capacitor comprising:
a storage electrode being at least partially formed above the substrate surface;
a dielectric layer being formed adjacent the storage electrode; and
a counter electrode, formed adjacent the dielectric layer, the counter electrode being isolated from the storage electrode by the dielectric layer;
wherein the storage electrode is formed as a body which is delimited by at least one set comprising two contiguous planes, the two planes extending perpendicularly with respect to the substrate surface, a point of intersection of normals of the two planes lying outside the body.

12. A storage capacitor according to claim 1 1, wherein the storage electrode has the shape of a cross in a cross-section parallel to the substrate surface.

13. A storage capacitor according to claim 11, further comprising a support structure made of an isolating material, the support structure being in contact with at least two circumferential points of the body of the storage electrode.

14. A storage capacitor according to claim 11, wherein, in a cross-section parallel to the substrate surface, the body comprises at least three crossing beams.

15. A storage capacitor according to claim 11, wherein in a cross-section parallel to the substrate surface the body comprises at least three contiguous beams.

16. A storage capacitor, suitable for use in a DRAM cell, the storage capacitor being at least partially formed above a substrate surface, the storage capacitor comprising:
a first storage electrode being at least partially formed above the substrate surface, the first storage electrode being formed as a body which is delimited by at least one curved surface, the at least curved surface having a center of curvature outside the body in a plane parallel to the substrate surface;
a second storage electrode being formed above the first storage electrode and being electrically connected with the first storage electrode;
a dielectric layer being formed adjacent the first and second storage electrodes; and
a counter electrode, formed adjacent the dielectric layer, the counter electrode being isolated from the first and second storage electrode by the dielectric layer.

17. A storage capacitor according to claim 16, further comprising a support structure made of an isolating material, the support structure being in contact with at least two circumferential points of the body of the first storage electrode.

18. A storage capacitor according to claim 16, wherein the second storage electrode is formed as a body which is delimited at least one set comprising two contiguous planes, the two planes extending perpendicularly with respect to the substrate surface, a point of intersection of normals of the two planes lying outside the body.

19. A storage capacitor according to claim 16, wherein the second storage electrode is formed as a body which is delimited by at least one curved surface, the at least curved surface having a center of curvature outside the body in a plane parallel to the substrate surface.

20. A storage capacitor, suitable for use in a DRAM cell, the storage capacitor being at least partially formed above a substrate surface, the storage capacitor comprising:
a first storage electrode being at least partially formed above the substrate surface, the first storage electrode being formed as a body which is delimited at least one set comprising two contiguous planes, the two planes extending perpendicularly with respect to the substrate surface, a point of intersection of normals of the two planes lying outside the body;
a second storage electrode being formed above the first storage electrode and being electrically connected with the first storage electrode;
a dielectric layer being formed adjacent the first and second storage electrodes; and
a counter electrode, formed adjacent the dielectric layer, the counter electrode being isolated from the first and second storage electrodes by the dielectric layer.

21. An array of storage capacitors, each of the storage capacitors being at least partially formed above a substrate surface, each of the storage capacitors comprising:
a storage electrode being at least partially formed above the substrate surface;
a dielectric layer being formed adjacent the storage electrode; and
a counter electrode, formed adjacent the dielectric layer, the counter electrode being isolated from the storage electrode by the dielectric layer, wherein the storage electrode is formed as a body which is delimited by at least one curved surface, the at least curved surface having a center of curvature outside the body in a plane parallel to the substrate surface,
wherein the array comprises first and second sets of storage capacitors, the storage capacitors of the first set being rotated around an axis perpendicular to the substrate surface with respect to the storage capacitors of the second set, each of the storage capacitors of the first set being disposed adjacent at least one storage capacitor of the second set.

22. An array of storage capacitors, each of the storage capacitors being at least partially formed above a substrate surface, each of the storage capacitors comprising:
a storage electrode being at least partially formed above the substrate surface;
a dielectric layer being formed adjacent the storage electrode; and
a counter electrode formed adjacent the dielectric layer, the counter electrode being isolated from the storage electrode by the dielectric layer, wherein the storage electrode is formed as a body which is delimited by at least one set comprising two contiguous planes, the two planes extending perpendicularly with respect to the substrate surface, a point of intersection of normals of the two planes lying outside the body,
wherein the array comprises first and second sets of storage capacitors, the storage capacitors of the first set being rotated around an axis perpendicular to the substrate surface with respect to the storage capacitors of the second set, each of the storage capacitors of the first set being disposed adjacent at least one storage capacitor of the second set.

23. An array of storage capacitors, each of the storage capacitors being at least partially formed above a substrate surface, each of the storage capacitors comprising:
a storage electrode being at least partially formed above the substrate surface;
a dielectric layer being formed adjacent the storage electrode; and
a counter electrode formed adjacent the dielectric layer, the counter electrode being isolated from the storage electrode by the dielectric layer, wherein the storage electrode is formed as a body which is delimited by at least one curved surface, the at least curved surface having a center of curvature outside the body in a plane parallel to the substrate surface,
wherein the array comprises first and second sets of storage capacitors, the storage capacitors of the first and second sets being arranged in a lattice, respectively, wherein a distance of adjacent storage capacitors in a first direction is value “a” and a distance of adjacent storage capacitors in a second direction is value “b”, the first direction being perpendicular to the second direction, wherein the lattice of the first set of storage capacitors is translated with respect to the lattice of the second set of storage capacitors by a distance in the first direction smaller than value “a” and a distance in a second direction smaller than value “b”.

24. An array of storage capacitors, each of the storage capacitors being at least partially formed above a substrate surface, each of the storage capacitors comprising:
a storage electrode being at least partially formed above the substrate surface;
a dielectric layer being formed adjacent the storage electrode; and
a counter electrode formed adjacent the dielectric layer, the counter electrode being isolated from the storage electrode by the dielectric layer, wherein the storage electrode is formed as a body which is delimited by at least one set comprising two contiguous planes, the two planes extending perpendicularly with respect to the substrate surface, a point of intersection of normals of the two planes lying outside the body,
wherein the array comprises first and second sets of storage capacitors, the storage capacitors of the first and second sets being arranged in a lattice, respectively, wherein a distance of adjacent storage capacitors in a first direction is value “a” and a distance of adjacent storage capacitors in a second direction is value “b”, the first direction being perpendicular to the second direction, wherein the lattice of the first set of storage capacitors is translated with respect to the lattice of the second set of storage capacitors by a distance in the first direction smaller than value “a” and a distance in a second direction smaller than value “b”.

25. A memory cell array which is at least partially formed in a semiconductor substrate having a surface, the memory cell array comprising:
a plurality of transistors, each comprising a first and a second source/drain regions, a channel connecting the first and the second source/drain regions, and a gate electrode which is adapted to control a conductivity of the channel, and a plurality of storage capacitors, each comprising:
a storage electrode being at least partially formed above the substrate surface;
a dielectric layer being formed adjacent the storage electrode; and
a counter electrode, formed adjacent the dielectric layer, the counter electrode being isolated from the storage electrode by the dielectric layer,
wherein the storage electrode is formed as a body which is delimited by at least one curved surface, the at least curved surface having a center of curvature outside the body in a plane parallel to the substrate surface, wherein the storage electrode is electrically connected with one of the first and second source/drain regions.

26. A memory cell array which is at least partially formed in a semiconductor substrate having a surface, the memory cell array comprising:
a plurality of transistors, each comprising a first and a second source/drain regions, a channel connecting the first and the second source/drain regions, and a gate electrode which is adapted to control a conductivity of the channel, and a plurality of storage capacitors, each comprising:
a storage electrode being at least partially formed above the substrate surface;
a dielectric layer being formed adjacent the storage electrode; and
a counter electrode, formed adjacent the dielectric layer, the counter electrode being isolated from the storage electrode by the dielectric layer, wherein the storage electrode is formed as a body which is delimited by at least one set comprising two contiguous planes, the two planes extending perpendicularly with respect to the substrate surface, a point of intersection of normals of the two planes lying outside the body, wherein the storage electrode is electrically connected with one of the first and second source/drain regions.
